(19) United States
(12) Patent Application Publication
(10) Pub. No.: US 2025/0349734 A1
(43) Pub. Date: Nov. 13, 2025

(54) PICK-AND-PLACE ALIGNMENT MARKS FOR SEMICONDUCTOR PACKAGE STRUCTURES AND METHODS OF MAKING THE SAME

(71) Applicant: Taiwan Semiconductor Manufacturing Company Limited, Hsinchu (TW)

(72) Inventors: Ting-Yi Lin, Taoyuan City (TW); Ting-Yang Yu, Hsinchu (TW); Ming-Tan Lee, Kaohsiung City (TW); Hung-Jui Kuo, Hsinchu City (TW)

(21) Appl. No.: 18/661,037

(22) Filed: May 10, 2024

(51) Int. Cl. H01L 23/544; H01L 21/48; H01L 23/00; H01L 23/31; H01L 23/498; H01L 25/18

(52) U.S. Cl. CPC H01L 23/544; H01L 21/486; H01L 23/31; H01L 23/49838; H01L 25/18; H01L 24/08; H01L 24/16; H01L 24/32; H01L 24/73; H01L 2223/54426; H01L 2224/08225; H01L 2224/16225; H01L 2224/32225; H01L 2224/73204; H01L 2225/06517; H01L 2225/06548; H01L 2924/1436

(57) ABSTRACT

An embodiment semiconductor package may include a semiconductor device, a molding material laterally surrounding the semiconductor device, and an alignment mark including a first through-molding-via (TMV) and a second TMV, each formed in the molding material. The first TMV may have a first specific dimension that is between 10 microns and 150 microns and the second TMV may have a second specific dimension that is between 100 microns and 500 microns. One or more first TMVs may be located in a first region and one or more second TMVs may be located in a second region that surrounds the first region. The first region may have a diameter that is between 100 microns and 1000 microns and the second region may be an annular region having an inner diameter that is between 120 microns and 1600 microns and an outer diameter that is between 270 microns and 2000 microns.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits are typically manufactured on a single semiconductor wafer, and individual dies on the wafer may be singulated by sawing between the integrated circuits along scribe lines. The individual dies are typically packaged separately, in multi-chip modules, or in other types of packaging, for example.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), 3-dimensional integrated circuits (3DICs), wafer level packages (WLPs), package on package (PoP), System on Chip (SoC) or System on Integrated Circuit (SoIC) devices. Some of these 3-dimensional devices (e.g., 3DIC, SoC, SoIC) are prepared by placing chips over chips on a semiconductor wafer level. These 3-dimensional devices provide improved integration density and other advantages, such as faster speeds and higher bandwidth, because of the decreased length of interconnects between the stacked chips. However, there are many challenges related to 3-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is vertical cross-sectional exploded view of components of a related semiconductor package during a package assembly and surface mounting process.

FIG. 2 is a vertical cross-sectional view illustrating a related assembled semiconductor package mounted onto a support substrate.

FIG. 3 is a vertical cross-sectional view of a further semiconductor package including an integrated fan-out package, according to various embodiments.

FIG. 4A is a vertical cross-sectional view of an intermediate structure that may be used in the formation of a semiconductor package, according to various embodiments.

FIG. 4B is a vertical cross-sectional view of a further intermediate structure that may be used in the formation of a semiconductor package, according to various embodiments.

FIG. 4C is a vertical cross-sectional view of a further intermediate structure that may be used in the formation of a semiconductor package, according to various embodiments.

FIG. 4D is a vertical cross-sectional view of a further intermediate structure that may be used in the formation of a semiconductor package, according to various embodiments.

FIG. 4E is a vertical cross-sectional view of a further intermediate structure that may be used in the formation of a semiconductor package, according to various embodiments.

FIG. 4F is a vertical cross-sectional view of a further intermediate structure that may be used in the formation of a semiconductor package, according to various embodiments.

FIG. 4G is a vertical cross-sectional view of a further intermediate structure that may be used in the formation of a semiconductor package, according to various embodiments.

FIG. 5A is a top view of a wafer-level intermediate structure that may be used in the formation of a semiconductor package, according to various embodiments.

FIG. 5B is a top perspective view of a repeat unit of the intermediate structure of FIG. 5A, which may be used in the formation of a semiconductor package, according to various embodiments.

FIG. 5C is a top view of a wafer-level intermediate structure that may be used in the formation of a semiconductor package, showing four adjacent repeat units, according to various embodiments.

FIG. 5D is a top perspective view of a repeat unit of the intermediate structure of FIG. 5C, which may be used in the formation of a semiconductor package, according to various embodiments.

FIG. 6A is a top perspective view of a repeat unit of an intermediate structure that may be used in the formation of a semiconductor package, according to various embodiments.

FIG. 6B is a top view of a portion of the intermediate structure of FIG. 6A showing details of an alignment mark, according to various embodiments.

FIG. 6C is a vertical cross-sectional view of the repeat unit of FIG. 6A showing further details of the intermediate structure, according to various embodiments.

FIG. 7A is a top view of a wafer-level intermediate structure that may be used in the formation of a related semiconductor package.

FIG. 7B is a top view of a first portion of the intermediate structure of FIG. 7A showing through-molding-vias (TMVs) that may be used as alignment marks.

FIG. 7C is a vertical cross-sectional view of the first portion of the intermediate structure of FIG. 7A showing non-uniformities of TMVs.

FIG. 7D is a top view of a second portion of the intermediate structure of FIG. 7A showing through-molding-vias (TMVs) that may be used as alignment marks.

FIG. 7E is a vertical cross-sectional view of the second portion of the intermediate structure of FIG. 7A showing non-uniformities of TMVs.

FIG. 7F is a top view of a further wafer-level intermediate structure that may be used in the formation of a semiconductor package, according to various embodiments.

FIG. 7G is a top view of a first portion of the intermediate structure of FIG. 7F showing details of a first alignment mark including a plurality of first TMVs and a plurality of second TMVs, according to various embodiments.

FIG. 7H is a vertical cross-sectional view of the first portion of the intermediate structure of FIG. 7F showing improved uniformity of the first TMVs, according to various embodiments.

FIG. 7I is a top view of a second portion of the intermediate structure of FIG. 7F showing details of a second alignment mark including a plurality of first TMVs and a plurality of second TMVs, according to various embodiments.

FIG. 7J is a vertical cross-sectional view of the second portion of the intermediate structure of FIG. 7F showing improved uniformity of the first TMVs, according to various embodiments.

FIG. 8A is a top view of an alignment mark including first TMVs and second TMVs, according to various embodiments.

FIG. 8B is an enlarged top view of the alignment mark of FIG. 8A showing geometric details of the first TMVs and second TMVs, according to various embodiments.

FIG. 8C is a top view of a further alignment mark including a plurality of first TMVs and a single second TMV, according to various embodiments.

FIG. 8D is a top view of a further alignment mark including a single first TMV and a plurality of second TMVs, according to various embodiments.

FIG. 9 illustrates top views of various types of TMVs that may be used to form an alignment mark, according to various embodiments.

FIG. 10A is a vertical cross sectional view of an intermediate structure that may be used in the formation of a semiconductor package, according to various embodiments.

FIG. 10B is a vertical cross sectional view of a further intermediate structure that may be used in the formation of a semiconductor package, according to various embodiments.

FIG. 10C is a vertical cross sectional view of a further intermediate structure that may be used in the formation of a semiconductor package, according to various embodiments.

FIG. 10D is a vertical cross sectional view of a further intermediate structure that may be used in the formation of a semiconductor package, according to various embodiments.

FIG. 11A is a vertical cross sectional view of an intermediate structure that may be used in the formation of a semiconductor package, according to various embodiments.

FIG. 11B is a vertical cross sectional view of a further intermediate structure that may be used in the formation of a semiconductor package, according to various embodiments.

FIG. 11C is a vertical cross sectional view of a further intermediate structure that may be used in the formation of a semiconductor package, according to various embodiments.

FIG. 11D is a vertical cross sectional view of a further intermediate structure that may be used in the formation of a semiconductor package, according to various embodiments.

FIG. 11E is a vertical cross sectional view of a further intermediate structure that may be used in the formation of a semiconductor package, according to various embodiments.

FIG. 12A is a vertical cross sectional view of an intermediate structure that may be used in the formation of a semiconductor package, according to various embodiments.

FIG. 12B is a vertical cross sectional view of a further intermediate structure that may be used in the formation of a semiconductor package, according to various embodiments.

FIG. 12C is a vertical cross sectional view of a further intermediate structure that may be used in the formation of a semiconductor package, according to various embodiments.

FIG. 12D is a vertical cross sectional view of a further intermediate structure that may be used in the formation of a semiconductor package, according to various embodiments.

FIG. 13A is a vertical cross sectional view of an intermediate structure that may be used in the formation of a semiconductor package, according to various embodiments.

FIG. 13B is a vertical cross sectional view of a further intermediate structure that may be used in the formation of a semiconductor package, according to various embodiments.

FIG. 13C is a vertical cross sectional view of a further intermediate structure that may be used in the formation of a semiconductor package, according to various embodiments.

FIG. 13D is a vertical cross sectional view of a further intermediate structure that may be used in the formation of a semiconductor package, according to various embodiments.

FIG. 13E is a vertical cross sectional view of a further intermediate structure that may be used in the formation of a semiconductor package, according to various embodiments.

FIG. 14 is a flowchart illustrating process operations of a method of forming a semiconductor package, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies/devices (i.e., “chips”) may be mounted onto a common substrate, which may also be referred to as a “package substrate.” In some embodiments, electrical connections to the semiconductor package may be made by mounting the package substrate onto a support substrate containing electrical interconnects, such as a printed circuit board (PCB). A semiconductor package may further include an interposer to which one or more semiconductor dies are attached and electrically coupled. The interposer, in turn, may be attached and electrically coupled to a package substrate, which may be further attached to a PCB. As such, separate structures (e.g., semiconductor dies, interposer, package substrate, and PCB) may be fabricated and then assembled.

Disclosed embodiments may provide advantages over existing semiconductor packages. For example, in an embodiment, a semiconductor package may include alignment marks having a first through-molding-via (TMV) and a second TMV. The second TMV may have a dimension (e.g., side, width, diameter, etc.) that is larger than a corresponding dimension of a first TMV. The first TMV and second TMV may be formed by an electroplating process and the presence of the larger second TMV may act to regulate an electroplating current density to have a more uniform spatial distribution than may otherwise occur in instances in which all of the TMVs (first TMV and second TMV) were the same size. In this regard, a resulting specific diameter uniformity and coplanarity of the resulting TMVs may be improved. As such, the smaller dimensions of the first TMVs may allow for increased positioning accuracy when used as alignment markers in a pick-and-place process that may be used to position semiconductor devices within the semiconductor package.

An embodiment semiconductor package may include a semiconductor device, a molding material laterally surrounding the semiconductor device, and an alignment mark including a first TMV and a second TMV, each formed in the molding material. The first TMV may have a first specific dimension that is between 10 microns and 150 microns and the second TMV may have a second specific dimension that corresponds to the first specific dimension such that the second specific dimension is between 100 microns and 500 microns. One or more first TMVs may be located in a first region and one or more second TMVs may be located in a second region that surrounds the first region. The first region may have a diameter that is between 100 microns and 1000 microns and the second region may be an annular region having an inner diameter that is between 120 microns and 1600 microns and an outer diameter that is between 270 microns and 2000 microns.

According to a further embodiment, a semiconductor package may include a molding material having a rectangular slab geometry including a length direction, a width direction, and a thickness direction, an alignment mark including a first TMV and a second TMV each formed in the molding material and having a respective symmetry axis parallel to the thickness direction, such that the first TMV includes a first specific dimension and the second TMV includes a second specific dimension that that corresponds to the first specific dimension and the second specific dimension is larger than the first specific dimension. The semiconductor package may further include a plurality of third TMVs formed in the molding material, each including a further symmetry axis parallel to the thickness direction, such that the plurality of third TMVs is configured in a rectangular arrangement around a perimeter of a first rectangular region in a plane spanned by the length direction and the width direction.

An embodiment method of forming a semiconductor package may include forming a plurality of conductive vias over a substrate including an alignment mark formed of a first conductive via and a second conductive via, such that the first conductive via has a first specific dimension and the second conductive via has a second specific dimension that that corresponds to the first specific dimension and is greater than the first specific dimension; positioning a semiconductor device over the substrate and aligning the semiconductor device relative to the alignment mark; attaching the semiconductor device to the substrate; and forming a molding material around the semiconductor device and the plurality of conductive vias such that the plurality of conductive vias include a corresponding plurality of TMVs.

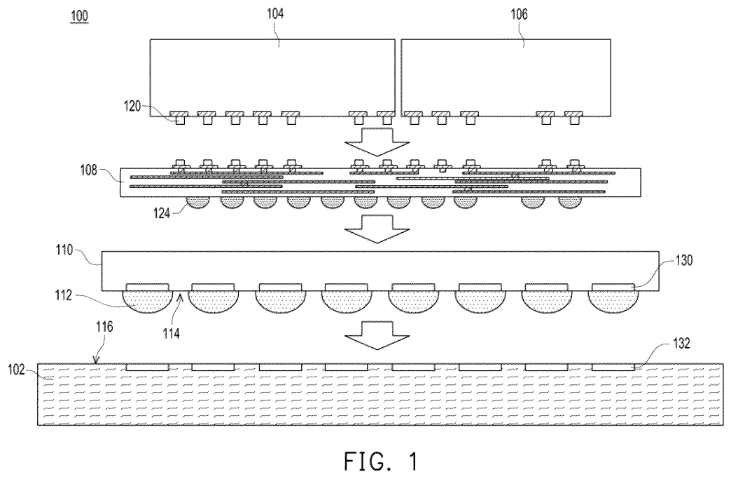

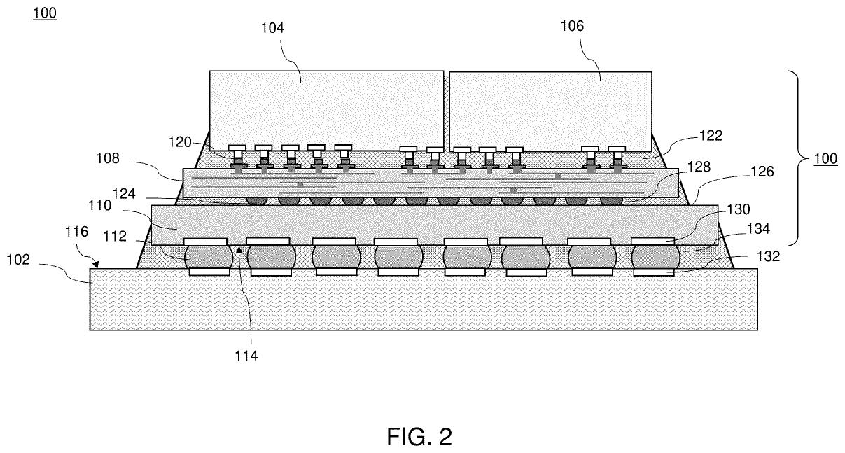

FIG. 1 is vertical cross-section exploded view of components of a related semiconductor package 100 during a package assembly and surface mounting process. FIG. 2 is a vertical cross-section view illustrating the related assembled semiconductor package 100 mounted onto the surface of a support substrate 102, such as a printed circuit board (PCB). The semiconductor package 100 in this example is a chip-on-wafer-on-substrate (CoWoS) semiconductor package, although it will be understood that a similar assembly and mounting process may be utilized for other types of semiconductor packages, such as integrated fan-out (InFO) semiconductor packages, flip-chip semiconductor packages, etc.

Referring to FIGS. 1 and 2, the related semiconductor package 100 may include integrated circuit (IC) semiconductor devices, such as first semiconductor devices 104 and second semiconductor devices 106. During the package assembly process, the first semiconductor device 104 and the second semiconductor device 106 may be mounted on an interposer 108. The interposer 108 containing the first semiconductor device 104 and the second semiconductor device 106 may be mounted onto a package substrate 110 to form a semiconductor package 100. The semiconductor package 100 may then be mounted to a support substrate 102, such as a printed circuit board (PCB), by mounting the package substrate 110 to the support substrate 102 using an array of first solder balls 112 on the lower surface 114 of the package substrate 110.

A parameter that may ensure proper interconnection between the package substrate 110 and the support substrate 102 is the degree of co-planarity between the surfaces of the first solder balls 112 that may be brought into contact with the mounting surface (i.e., the upper surface 116 of the support substrate 102 in FIG. 1). A low degree of co-planarity between the first solder balls 112 may result in instances of solder cold joints (i.e., insufficient melting of the solder material, resulting in a poor bond that is susceptible to cracking and separation) and/or solder bridging issues (i.e., solder material from one solder ball 112 contacting material from a neighboring solder ball 112, resulting in an unintended connection (i.e., electrical short)) during the reflow process.

Deformation of the package substrate 110, such as stress-induced warping of the package substrate 110, may be a contributor to low co-planarity of the first solder balls 112 during surface mounting of the package substrate 110 onto a support substrate 102. Deformation of the package substrate 110 is not an uncommon occurrence, particularly in the case of semiconductor packages 100 used in high-performance computing applications. These high-performance semiconductor packages 100 tend to be relatively large and may include a number of semiconductor devices (e.g., 104, 106) mounted to the package substrate 110, which may increase a likelihood that the package substrate 110 may be subject to warping or other deformations. Such deformations may present challenges to effective solder mounting of these types of semiconductor package substrates 110 onto a support substrate 102.

In various embodiments, the first semiconductor devices 104 may be three-dimensional devices, such as three-dimensional integrated circuits (3DICs), System on Chip (SoC) or System on Integrated Chips (SoIC) devices (i.e., stacked chips that are bonded using hybrid bonding). A three-dimensional semiconductor device 104 may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor device 104 may also be referred to as a “first die stack.”

The second semiconductor device(s) 106 may be different from the first semiconductor device(s) 104 in terms of their structure, design and/or functionality. The one or more second semiconductor devices 106 may be three-dimensional semiconductor devices, which may also be referred to as “second die stacks.” In some embodiments, the one or more second semiconductor devices 106 may include a memory device, such as a high bandwidth memory (HBM) device. In the example shown in FIGS. 1 and 2, the semiconductor package 100 may include a SoC die stack 104 and an HBM die stack 106, although it will be understood that the semiconductor package 100 may include greater or fewer numbers of semiconductor devices.

Referring again to FIG. 2, the first semiconductor devices 104 and second semiconductor devices 106 may be mounted on an interposer 108. In some instances, the interposer 108 may be an organic interposer including a polymer dielectric material (e.g., a polyimide material) having a plurality of metal interconnect structures extending therethrough. In other instances, the interposer 108 may be a semiconductor interposer, such as a silicon interposer, having a plurality of interconnect structures (e.g., through-silicon vias) extending therethrough. Other suitable configurations for the interposer 108 are within the contemplated scope of this disclosure. The interposer 108 may include a plurality of conductive bonding pads on upper and lower surfaces of the interposer and a plurality of conductive interconnects extending through the interposer 108 between the upper and lower bonding pads of the interposer 108. The conductive interconnects may distribute and route electrical signals between the first semiconductor devices 104, the second semiconductor devices 106, and the underlying package substrate 110.

A plurality of first metal bumps 120, such as microbumps, may electrically connect conductive bonding pads on the bottom surfaces of the first semiconductor devices 104 and second semiconductor devices 106 to the conductive bonding pads on the upper surface of the interposer 108. In one non-limiting embodiment, first metal bumps 120 in the form of microbumps may include a plurality of first metal stacks, such as a plurality of Cu—Ni—Cu stacks, located on the bottom surfaces of the first semiconductor devices 104 and second semiconductor devices 106, and a plurality of second metal stacks (e.g., Cu—Ni—Cu stacks) located on the upper surface of the interposer 108. A solder material, such as tin (Sn), may be located between respective first and second metal stacks to electrically connect the first semiconductor devices 104 and the second semiconductor devices 106 to the interposer 108. Other suitable materials for the first metal bumps 120 and solder material are within the contemplated scope of disclosure.

After the first semiconductor devices 104 and second semiconductor devices 106 are mounted to the interposer 108, a first underfill material portion 122 may optionally be provided in the spaces surrounding the first metal bumps 120 and between the bottom surfaces of the first semiconductor devices 104, the second semiconductor devices 106, and the upper surface of the interposer 108 as shown in FIG. 2. The first underfill material portion 122 may also be provided in the spaces laterally separating adjacent first semiconductor devices 104 and second semiconductor devices 106 of the semiconductor package 100. In various embodiments, the first underfill material portion 122 may include of an epoxy-based material, which may include a composite of resin and filler materials.

Referring again to FIG. 2, the interposer 108 may be mounted on the package substrate 110 that may provide mechanical support for the interposer 108 and the first semiconductor devices 104 and second semiconductor devices 106 that are mounted on the interposer 108. The package substrate 110 may include a suitable material, such as an organic material (e.g., a polymer and/or thermoplastic material), a semiconductor material (e.g., a semiconductor wafer, such as a silicon wafer), a ceramic material, a glass material, combinations thereof, etc. Other suitable substrate materials are within the contemplated scope of this disclosure. In various embodiments, the package substrate 110 may include a plurality of conductive bonding pads (not shown) in an upper surface 126 of the package substrate 110. A plurality of second metal bumps 124, such as C4 solder bumps, may electrically connect conductive bonding pads (not shown) on the bottom surface of the interposer 108 to the conductive bonding pads on the upper surface 126 of the package substrate 110. In various embodiments, the second metal bumps 124 may include a suitable solder material, such as tin (Sn), although other suitable solder materials are within the contemplated scope of disclosure.

A second underfill material portion 128 may be provided in the spaces surrounding the second metal bumps 124 and between the bottom surface of the interposer 108 and the upper surface 126 of the package substrate 110 as illustrated, for example, in FIG. 2. In various embodiments, the second underfill material portion 128 may include an epoxy-based material, which may include a composite of resin and filler materials. In some embodiments, a lid or cover (not shown in FIGS. 1 and 2) may be mounted to the package substrate 110 and may provide an enclosure around the upper and side surfaces of the first semiconductor devices 104 and second semiconductor devices 106.

As described above, the package substrate 110 may be mounted to the support substrate 102, such as a printed circuit board (PCB). Other suitable support substrates 102 are within the contemplated scope of disclosure. The package substrate 110 may include a plurality of conductive bonding pads 130 in a lower surface 114 of the package substrate 110. A plurality of conductive interconnects (not shown) may extend through the package substrate 110 between conductive bonding pads on the upper surface 126 and lower surface 114 of the package substrate 110. The plurality of first solder balls 112 (or bump structures) may electrically connect the conductive bonding pads 130 on the lower surface 114 of the package substrate 110 to a plurality of conductive bonding pads 132 on the upper surface 116 of the support substrate 102.

The conductive bonding pads 130 of the package substrate 110 and conductive bonding pads 132 of the support substrate 102 may be formed of a suitable conductive material, such as copper. Other suitable conductive materials are within the contemplated scope of disclosure. The plurality of first solder balls 112 on the lower surface 114 of the package substrate 110 may form an array of first solder balls 112, such as a ball grid array (BGA) that may include an array pattern that corresponds to an array pattern of the conductive bonding pads 132 on the upper surface 116 of the support substrate 102. In one non-limiting example, the array of first solder balls 112 may include a grid pattern and may have a pitch (i.e., distance between the center of each solder ball 112 and the center of each adjacent solder ball 112). In an example embodiment, the pitch may be between about 0.8 and 1.0 mm, although larger and smaller pitches may be used.

The first solder balls 112 may include any suitable solder material, such as tin, lead, silver, indium, zinc, nickel, bismuth, antimony, cobalt, copper, germanium, alloys thereof, combinations thereof, or the like. Other suitable materials for the first solder balls 112 are within the contemplated scope of disclosure. In some embodiments, the lower surface 114 of the package substrate 110 may include a coating of solder resist (SR) material (not shown), which may also be referred to as a “solder mask”. A SR material coating may provide a protective coating for the package substrate 110 and any underlying circuit patterns formed on or within the package substrate 110. An SR material coating may also inhibit solder material from adhering to the lower surface 114 of the package substrate 110 during a reflow process. In embodiments in which the lower surface 114 of the package substrate 110 may include an SR coating, the SR material coating may include a plurality of openings through which the conductive bonding pads 130 may be exposed.

In various embodiments, each of the conductive bonding pads 130 in different regions of the package substrate 110 may have the same size and shape. In the embodiment shown in FIGS. 1 and 2, the surfaces of the conductive bonding pads 130 may be substantially co-planar with the lower surface 114 of the package substrate 110, which in some embodiments may include a solder resist (SR) coating. Alternatively, the surfaces of the conductive bonding pads 130 may be recessed relative to the lower surface 114 of the package substrate 110. In some embodiments, the surfaces of the conductive bonding pads 130 may be raised relative to the lower surface 114 of the package substrate 110.

Referring again to FIGS. 1 and 2, first solder balls 112 may be provided over the respective conductive bonding pads 130. In one non-limiting example, the conductive bonding pads 130 may have a width dimension that is between about 500 μm and about 550 μm (e.g., ˜530 μm), and the first solder balls 112 may have an outer diameter that may be between about 600 μm and about 650 μm (e.g., ˜630 μm), although greater and smaller sizes of the first solder balls 112 and/or the conductive bonding pads 130 are within the contemplated scope of disclosure.

A first solder reflow process may include subjecting the package substrate 110 to an elevated temperature (e.g., at least about 250° C.) in order to melt the first solder balls 112 and to cause the first solder balls 112 to adhere to the conductive bonding pads 130. Following the first reflow process, the package substrate 110 may be cooled causing the first solder balls 112 to re-solidify. Following the first solder reflow process, the first solder balls 112 may adhere to the conductive bonding pads 130. Each solder ball 112 may extend from the lower surface 114 of the package substrate 110 by a vertical height that may be less than the outer diameter of the solder ball 112 prior to the first reflow process. For example, where the outer diameter of the solder ball 112 is between about 600 μm and about 650 μm (e.g., ˜630 μm), the vertical height of the solder ball 112 following the first reflow process may be between about 500 μm and about 550 μm (e.g., ˜520 μm).

In various embodiments, the process of mounting the package substrate 110 onto the support substrate 102 as shown in FIG. 2, may include aligning the package substrate 110 over the support substrate 102, such that the first solder balls 112 contacting the conductive bonding pads 130 of the package substrate 110 may be located over corresponding bonding pads (e.g., conductive bonding pads 132) on the support substrate 102. A second solder reflow process may then be performed. The second solder reflow process may include subjecting the package substrate 110 to an elevated temperature (e.g., at least about 250° C.) to thereby melt the first solder balls 112 and cause the first solder balls 112 to adhere to the corresponding conductive bonding pads 132 on the support substrate 102. Surface tension may cause the semi-liquid solder to maintain the package substrate 110 in alignment with the support substrate 102 while the solder material cools and solidifies. Upon solidification of the first solder balls 112, the package substrate 110 may sit above the upper surface 116 of the support substrate 102 by a stand-off height that may be between about 0.4 mm to about 0.5 mm, although greater or lesser stand-of heights are within the contemplated scope of disclosure.

Following the mounting of the package substrate 110 to the support substrate 102, a third underfill material portion 134 may be provided in the spaces surrounding the first solder balls 112 and between the lower surface 114 of the package substrate 110 and the upper surface 116 of the support substrate 102, as is shown in FIG. 2. In various embodiments, the third underfill material portion 134 may include an epoxy-based material, which may include a composite of resin and filler materials.

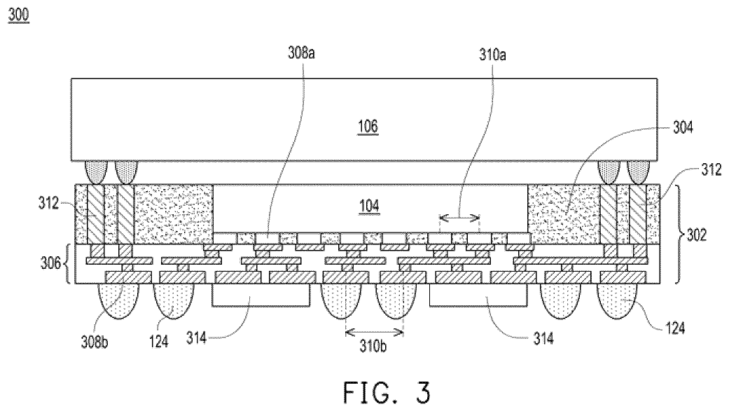

FIG. 3 is a vertical cross-sectional view of a further semiconductor package 300 including an integrated fan-out (InFO) package 302, according to various embodiments. The InFO package 302 may include a first semiconductor device 104 embedded within a molding material 304. The InFO package 302 may further include redistribution layers 306 formed directly on the molding material 304 and over a surface of the first semiconductor device 104. As shown, first bonding pads 308a of the first semiconductor device 104 may be electrically connected to the redistribution layers 306. The redistribution layers 306 may have a fan-out configuration such that second bonding pads 308b, formed on a side of the redistribution layers 306 opposite to the first semiconductor device 104, may have a second pitch 310b that is greater than a first pitch 310a of the first bonding pads 308a. As shown in FIG. 3, metal bumps (i.e., second metal bumps 124 described above with reference to FIGS. 1 and 2) may be formed on the second bonding pads 308b such that the InFO package 302 may be electrically attached to a package substrate 110 (e.g., see FIGS. 1 and 2).

The InFO package 302 may further include through-molding-vias (TMVs) 312 formed within the molding material 304. The TMVs 312 may provide electrical connections between the redistribution layers 306, formed on a first side (i.e., the bottom side in FIG. 3) of the InFO package 302 and electrical contacts (not shown) formed on a second side (i.e., the top side in FIG. 3) of the InFO package 302. In this regard, a second semiconductor device 106 may be stacked on the InFO package 302 and may be electrically connected to the TMVs 312. As such, the semiconductor package 300 may be configured as an integrated fan-out package-on-package (InFO_PoP) structure. In other embodiments, the InFO package 302 may further include additional redistribution layers (not shown) formed on the top side of the InFO package 302, which may provide additional electrical connections between the InFO package 302 and the second semiconductor device 106.

As described above, the first semiconductor device 104 and the second semiconductor device 106 may provide respective functionalities. For example, the first semiconductor device 104 may be a SoC die stack and the second semiconductor device 106 may be an HBM die stack. Although the semiconductor package 300 includes two semiconductor devices (104, 106), it will be understood that various numbers of semiconductor devices, providing respective functionalities, may be included in semiconductor packages in other embodiments. Additional circuit functionality may also be provided by one or more active or passive electrical devices 314 that may be attached to the redistribution layers 306 on the side of the redistribution layers 306 opposite to the first semiconductor device 104 (i.e., the bottom side of the InFO package 302), as shown in FIG. 3. The electrical devices 314 may include integrated passive devices (IPDs) that may include resistors, capacitors, inductors, diodes, etc. For example, in some embodiments, the passive electrical devices 314 may include deep trench capacitors (not shown). In further examples, the electrical devices 314 may include active devices including logic circuits, memory circuit elements, etc.

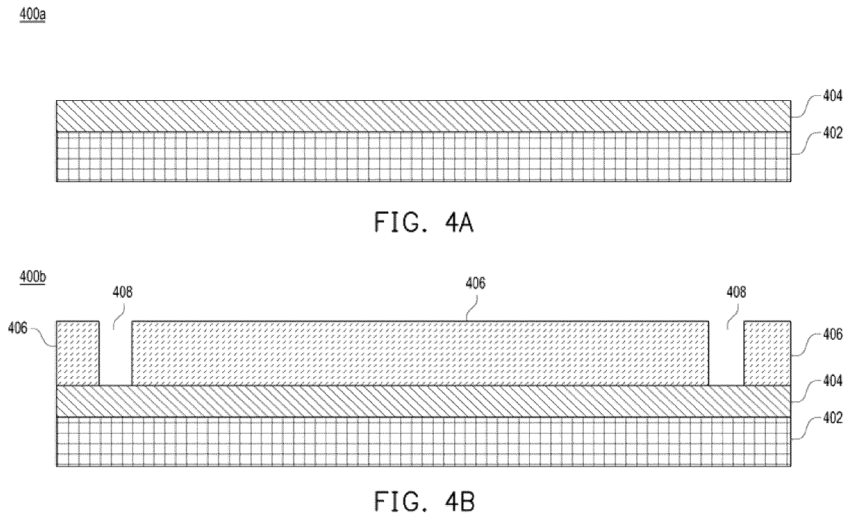

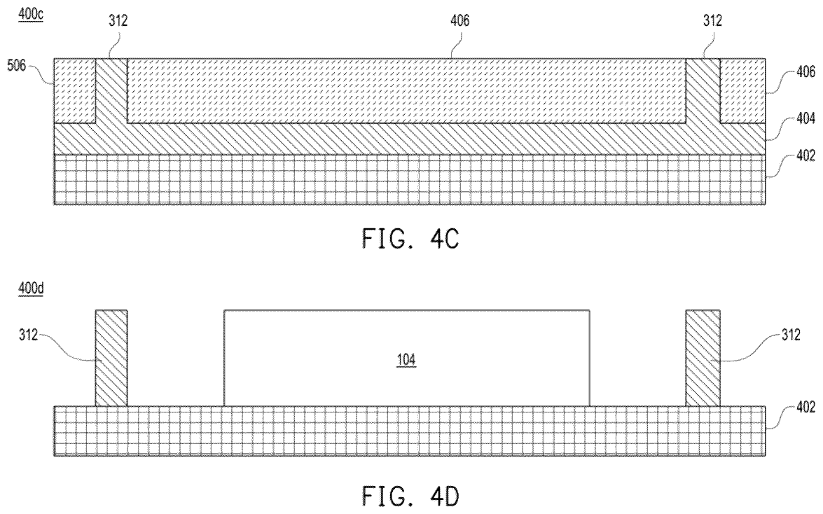

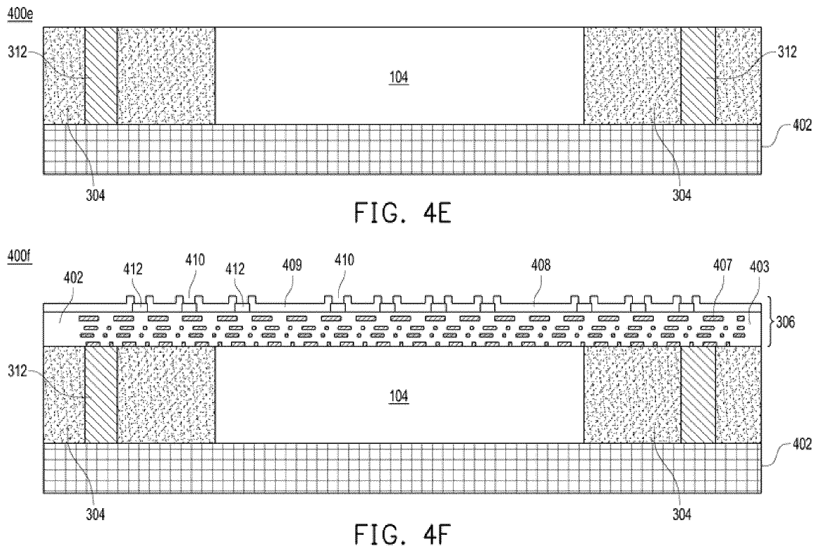

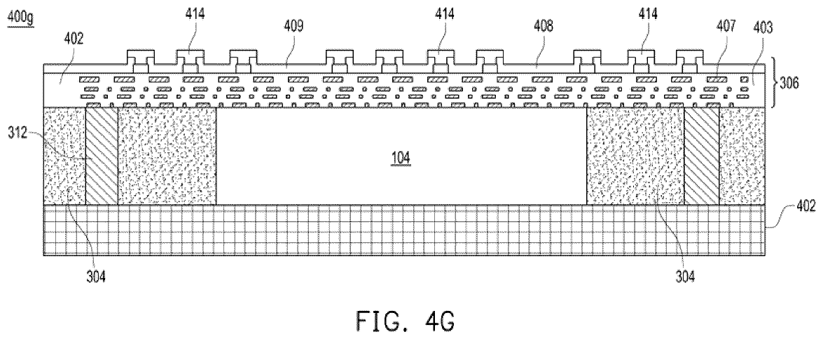

The presence of the InFO package 302 in the semiconductor package 300 of FIG. 3 may provide advantages over the semiconductor package 100 of FIGS. 1 and 2 by eliminating the need to form a separate interposer 108 to which the semiconductor devices (104, 106), of the semiconductor package 100, are attached (e.g., see FIG. 2). Further, by forming the redistribution layers 306 directly on the first semiconductor device 104, the first metal bumps 120 of FIGS. 1 and 2 may be avoided. The first underfill material portion 122 of the semiconductor package 100 (e.g., see FIG. 2) may likewise be avoided. As such, the InFO package 302 may avoid alignment and warpage problems that may otherwise occur when a separate interposer 108 is present in the semiconductor package 100. Further, the InFO package 302 may provide additional advantages by including the TMVs 312 that may provide electrical connections between a first side (i.e., the bottom side in FIG. 3) and a second side (i.e., the top side in FIG. 3) of the InFO package 302, thus allowing the InFO package 302 to be stacked with one or more additional packages (e.g., the second semiconductor device 106 of FIG. 3). An example process for forming an InFO package 302 is described with reference to FIGS. 4A to 4F, below.

FIGS. 4A, 4B, and 4C are vertical cross-sectional views of respective intermediate structures 400a, 400b, and 400c that may be used in the formation of a semiconductor package 302, according to various embodiments. The intermediate structure 400a may include a carrier substrate 402 having a seed layer 404 formed thereon. The seed layer 404 may be formed, for example, by sputtering. The intermediate structure 400b of FIG. 4B may include a patterned photoresist 406 formed over the seed layer 404. The patterned photoresist 406 may include openings 408 formed in the patterned photoresist 406. In the intermediate structure 400c of FIG. 4C, the TMVs 312 may be formed by electroplating a metallic fill material (such as copper, nickel, or a stack of copper and nickel) into the openings 408 of the patterned photoresist 406 of the intermediate structure 400b of FIG. 4B.

The metallic seed layer 404 may include, for example, a stack of a titanium barrier layer and a copper seed layer. The titanium barrier layer may have thickness in a range from 40 nm to 400 nm, and the copper seed layer may have a thickness in a range from 100 nm to 400 nm. The metallic fill material may include copper, nickel, or an alloy of copper and nickel. Other suitable metallic fill materials are within the contemplated scope of disclosure. After forming the TMVs 312, the patterned photoresist 406 may then be removed by ashing or dissolution in a solvent. Portions of the seed layer 404 may then be etched in regions between the electroplated metallic fill material portions to generate the TMVs 312 as separated structures formed on the carrier substrate 402 as shown, for example, in FIG. 4D.

FIG. 4D is a vertical cross-sectional view of a further intermediate structure 400d that may be used in forming the semiconductor package 302, according to various embodiments. As shown, the intermediate structure 400d may include the TMVs 312 attached to the carrier substrate 402, which may be formed by the process described with reference to FIGS. 4A to 4C, above. The intermediate structure 400d may further include a one or more semiconductor devices 104. The one or more semiconductor devices 104 may be attached to the carrier substrate 402, in a pick-and-place process, using a temporary adhesive layer (not shown), such a light-to-heat-conversion release (LTHC) coating, or another heat-deactivated adhesive.

FIG. 4E is a vertical cross-sectional view of a further intermediate structure 400e that may be used in forming the semiconductor package 302, according to various embodiments. The intermediate structure 400e may be formed from the intermediate structure 400d by forming a molding material 304 around the one or more semiconductor devices 104 and the TMVs 312. The molding material 304 may be an epoxy molding compound (EMC) that may be applied to the gaps between the one or more semiconductor devices 104 and the TMVs 312. The molding material 304 may be configured to provide mechanical support for the one or more semiconductor devices 104 and the TMVs 312. The EMC may include an epoxy-containing compound that may be hardened (i.e., cured) to provide a dielectric material portion having sufficient stiffness and mechanical strength. In this regard, a Young's modulus of pure epoxy is about 3.34 GPa, and a Young's modulus of the molding material 304 may be higher than the Young's modulus of pure epoxy by adding additives. As such, the Young's modulus of the molding material 304 may be greater than 3.4 GPa.

The EMC may include epoxy resin, hardener, silica (as a filler material), and other additives. The EMC may be provided in a liquid form or in a solid form depending on the viscosity and flowability. Liquid EMC may provide better handling, good flowability, fewer voids, better fill, and less flow marks. Solid EMC may provide reduced cure shrinkage, better stand-off, and reduced die drift. A high filler content (such as 84% in weight) within an EMC may shorten the time in mold, lower the mold shrinkage, and reduce the mold warpage. Uniform filler size distribution in the EMC may reduce flow marks and may enhance flowability. The curing temperature of the EMC may be in a range from 124° C. to 140° C. Portions of the molding material 304 that overlies a horizontal plane (including top surfaces of the one or more semiconductor devices 104) may be removed by a planarization process (e.g., using chemical mechanical planarization (CMP)).

FIG. 4F is a vertical cross-sectional view of a further intermediate structure 400f that may be used in the formation of the semiconductor package 302, according to various embodiments. As mentioned above with reference to FIG. 3, the intermediate structure 400f may include one or more redistribution layers 306 formed directly over the molding material 304 and over a surface of the first semiconductor device 104. A top surface of first semiconductor device 104 may include various electrical connections (not shown) that may be configured to be electrically coupled to the one or more redistribution layers 306 such that one or more redistribution layers 306 are electrically coupled to the first semiconductor device 104. For example, the first semiconductor device 104 may include first bonding pads 308a, as shown in FIG. 3.

The one or more redistribution layers 306 may be formed over the intermediate structure 400e and may be formed as a two-dimensional array. Specifically, a redistribution layer 306 may be formed within each of a plurality of unit areas of repetition (i.e., “repeat units”). Each repeat unit may correspond to an area associated with an InFO package 302 (e.g., see FIG. 3) to be individually diced. While FIG. 4F illustrates a region within a unit area, repetition of the structure illustrated in FIG. 4F in two horizontal directions during manufacturing is understood.

Each redistribution layer 306 may include redistribution dielectric layers 403 and redistribution wiring interconnects 407. The redistribution dielectric layers 403 may include a dielectric polymer material such as polyimide (PI), benzocyclobutene (BCB), or polybenzo-bisoxazole (PBO). Each redistribution dielectric layer 306 may be formed by spin coating and drying of the dielectric polymer material. The thickness of each redistribution dielectric layer 306 may be in a range from 2 microns to 40 microns, such as from 4 microns to 20 microns. Each redistribution dielectric layer 306 may be patterned, for example, by applying and patterning a respective photoresist layer there above, and by transferring the pattern in the photoresist layer into the redistribution dielectric layer 306 using an etch process such as an anisotropic etch process. The photoresist layer may be subsequently removed, for example, by ashing.

Each of the redistribution wiring interconnects 407 may be formed by depositing a metallic seed layer (not shown) by sputtering, by applying and patterning a photoresist layer (not shown) over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the redistribution wiring interconnects 407 may include copper, nickel, or copper and nickel. The thickness of the metallic fill material that is deposited for each redistribution wiring interconnect 407 may be in a range from 2 microns to 40 microns, such as from 4 microns to 10 microns, although smaller or larger thicknesses may also be used. The total number of levels of wiring in each a redistribution layer 306 (i.e., the levels of the redistribution wiring interconnects 407) may be in a range from 1 to 10.

A top surface of the one or more redistribution layers 306 may include a coating of solder resist (SR) material 409, which may also be referred to as a “solder mask.” The coating of SR material 409 (e.g., a polymer material) may provide a protective coating for the one or more redistribution layers 306 and any underlying circuit patterns formed on or within the intermediate structure 400e. An SR material 409 coating may also inhibit solder material from adhering to the top surface of the one or more redistribution layers 306 during a reflow process. The coating of SR material 409 may include a plurality of openings 410 through which redistribution bonding pads 412 may be exposed. The redistribution bonding pads 412 may be formed in the process used to form the one or more redistribution layers 306, and as such, may be electrically connected to the one or more redistribution layers 306. Additional electrical connections (e.g., bump structures) may then be formed over the first bonding pads 308a, as described in greater detail with reference to FIG. 4G, below.

FIG. 4G is a vertical cross-sectional view of a further intermediate structure 400g that may be used in the formation of the semiconductor package 302, according to various embodiments. As shown, the intermediate structure 400g may be formed from the intermediate structure 400f of FIG. 4F by formation of third metal bumps 414. The third metal bumps 414 may be formed as micro-bump structures. The third metal bumps 414 may be bump structures that may be subsequently used to electrically connect the active or passive electrical device 314 (e.g., integrated passive devices) to be subsequently bonded to a respective one of the one or more redistribution layers 306. A metallic fill material for the third metal bumps 414 may include copper. The third metal bumps 414 may have horizontal cross-sectional shapes of rectangles, rounded rectangles, or circles. Other horizontal cross-sectional shapes may be within the contemplated scope of disclosure. The third metal bumps 414 may be configured for micro-bump bonding (i.e., C2 bonding), and may have a thickness in a range from 30 microns to 100 microns, although smaller or larger thicknesses may also be used. In one embodiment, the third metal bumps 414 may be formed as an array of microbumps (such as copper pillars) having a lateral dimension in a range from 10 microns to 25 microns and having a pitch in a range from 20 microns to 50 microns.

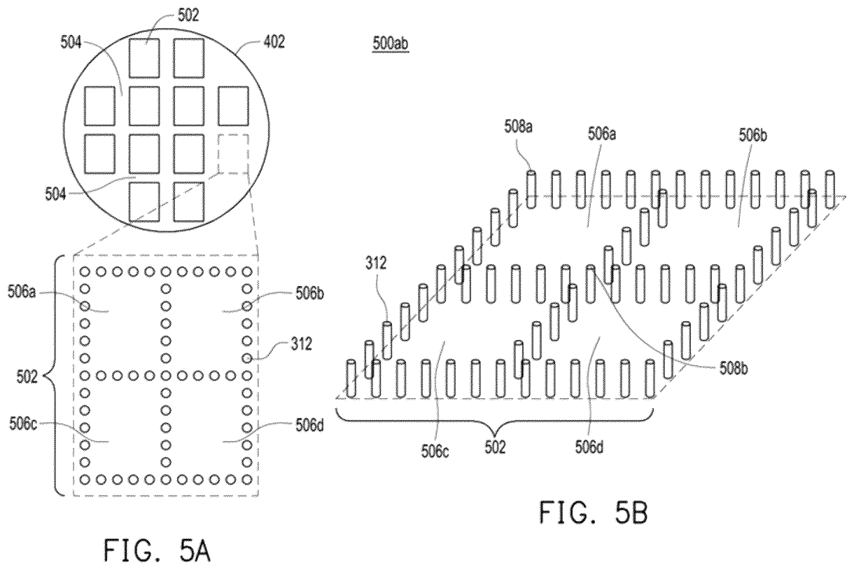

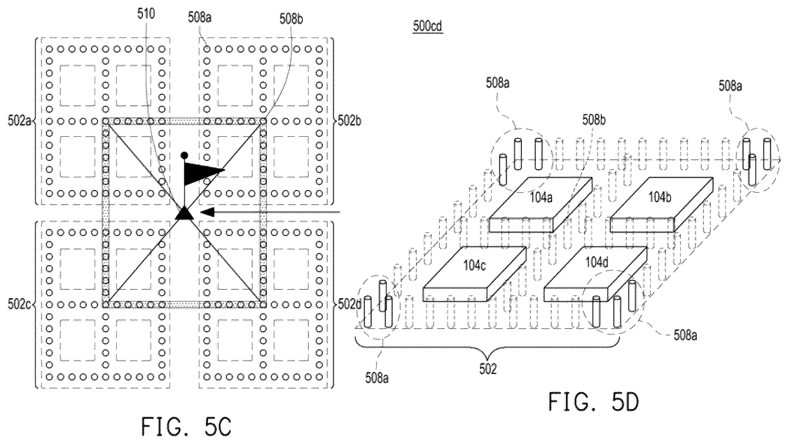

FIG. 5A is a top view of a wafer-level intermediate structure 500ab that may be used in the formation of the InFO package 302 of FIG. 3, according to various embodiments. FIG. 5B is a top perspective view of a repeat unit 502 of the intermediate structure 500ab of FIG. 5A, which may be used in the formation of the InFO package 302, according to various embodiments. As described above with reference to FIGS. 4A to 4D, a plurality of TMVs 312 may be formed over a carrier substrate 402. As shown in FIG. 5A, the TMVs 312 may be organized into a plurality of repeat units 502, which may be separated by scribe lines 504. As shown, a plurality of conductive vias 312 (i.e., TMVs) may be configured as one or more rectangular arrangements around respective perimeters of one or more corresponding rectangular regions (506a, 506b, 506c, 506d). In this example embodiment, each of the repeat units 502 include four rectangular regions (506a, 506b, 506c, 506d). However, in other embodiments, various numbers of the rectangular regions may be provided in each repeat unit 502.

Referring to FIGS. 5A-5E, each rectangular region (e.g., rectangular regions (506a, 506b, 506c, 506d)) within a repeat unit 502 may serve as an area in which a respective one of a plurality of semiconductor devices (e.g., semiconductor devices 104) may be attached, as described in greater detail with reference to FIG. 4D, above. In this regard, a pick-and-place process may be performed to place individual semiconductor devices within respective individual rectangular regions (506a, 506b, 506c, 506d). One or more of the TMVs 312 may be used as alignment marks (508a, 508b). In this regard, a pick-and-place tool (not shown) may use the alignment marks (508a, 508b) as reference points during the pick-and-place process to properly align the semiconductor devices (e.g., semiconductor devices 104a, 104b, 104c, 104d in FIG. 5E) relative to the rectangular regions (506a, 506b, 506c, 506d). As shown, a first type of TMV 508a may be located in corners of repeat units 502, and a second type of TMV 508b may be located in a center portion of a repeat unit 502.

FIG. 5C is a top view of a wafer-level intermediate structure 500cd, showing four adjacent repeat units (502a, 502b, 502c, 502d), which may be used in the formation of an InFO package 302, according to various embodiments. Each of the repeat units (502a, 502b, 502c, 502d) may be configured to be located at a pre-determined distance from a center 510 of the carrier substrate 402. In practice, however, once the repeat units (502a, 502b, 502c, 502d) are formed, there may be some deviation in the position of respective ones of the repeat units (502a, 502b, 502c, 502d). As such, a pick-and-place tool may measure a location of the center of each of the repeat units (502a, 502b, 502c, 502d) and may determine a positioning correction factor that may be used when positioning a corresponding plurality of semiconductor devices (104a, 104b, 104c, 104d) within respective rectangular regions (506a, 506b, 506c, 506d), as shown in FIG. 5D. In this regard, the center of each repeat unit (502a, 502b, 502c, 502d) may be defined by measuring a position of a center TMV 508b within each repeat unit (502a, 502b, 502c, 502d). As described in greater detail, below, each of the semiconductor devices (104a, 104b, 104c, 104d) may be first semiconductor devices 104 (e.g., SoC devices). Other semiconductor devices, such as second semiconductor devices 106 (e.g., HBM devices), or other types of semiconductor devices may be used in other embodiments.

FIG. 5D is a top perspective view of a repeat unit 502 of the intermediate structure 500cd of FIG. 5C, which may be used in the formation of an InFO package 302, according to various embodiments. As shown, positions of respective semiconductor devices (104b, 104b, 104c, 104d), to be subsequently attached, may be defined relative to measured positions of first alignment marks 508a and second alignment marks 508b. The defined positions may include location error correction factors based on actual positions of the alignment marks (508a, 508b), after fabrication, vs. designed locations of the alignment marks (508a, 508b).

FIG. 5E is a top perspective view of a repeat unit 502 of a further intermediate structure 500e, which may be used in the formation of an InFO package 302, according to various embodiments. As shown, the intermediate structure 500e may be formed by attaching a plurality of semiconductor devices (104a, 104b, 104c, 104d) to the intermediate structure 500cd of FIG. 5D. In this regard, a pick-and-place tool may place each of the semiconductor devices (104a, 104b, 104c, 104d) in the defined positions described above with reference to FIG. 5D. As described above, the defined positions may include adjustments to correct for errors in the placements of more alignment marks (508a, 508b).

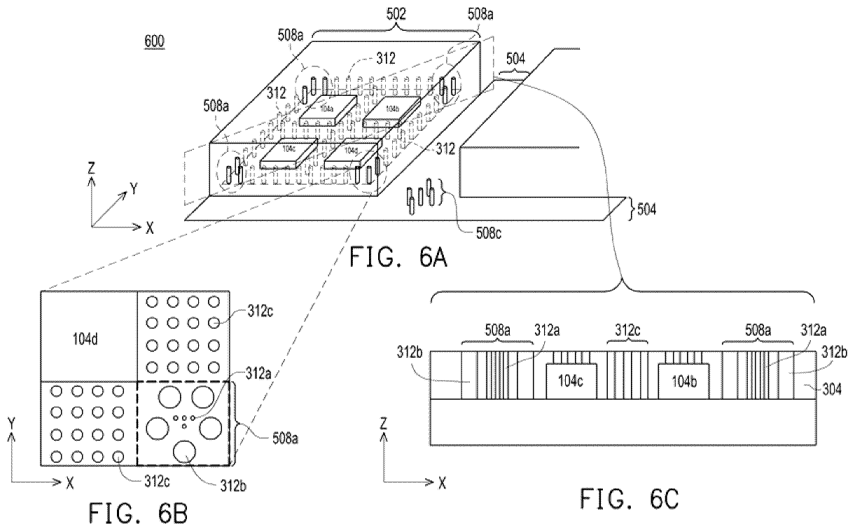

FIG. 6A is a top perspective view of a repeat unit 502 of an intermediate structure 600 that may be used in the formation of a semiconductor package 302, according to various embodiments. FIG. 6B is a top view of a portion of the intermediate structure 600 of FIG. 6A showing details of an alignment mark 508a and FIG. 6C is a vertical cross-sectional view of the repeat unit of FIG. 6A showing further details of the intermediate structure 600, according to various embodiments. The intermediate structure 600 may be similar to the intermediate structure 500e of FIG. 5E, but as shown in FIG. 6C, the intermediate structure 600 may further include a molding material 304 that is not shown in FIG. 6A to avoid obscuring the other details of FIG. 6A.

The intermediate structure 600 may include a plurality of semiconductor devices (104a, 104b, 104c, 104d) placed in rectangular areas that are bounded by a plurality of TMVs 312, as described above with reference to FIGS. 5A to 5E. As described above, each repeat unit 502 may be separated from adjacent repeat units by scribe lines 504 (also referred to as dicing lines or saw streets). As described above, one or more of the TMVs 312 may be used as alignment marks (508a, 508b). In this regard, as described above with reference to FIG. 5B, TMVs 312 may serve as corner alignment marks 508a or as center alignment marks 508b (not shown in FIGS. 6A to 6C). In further embodiments, one or more TMV's may be formed within one or more of the scribe lines 504 to thereby form scribe alignment marks 508c.

As shown in FIG. 6B, a corner alignment mark 508a may be formed as a group of TMVs that include a plurality of first TMVs 312a having a first specific dimension (e.g., a first cylindrical diameter) and a plurality of second TMVs 312b having a second specific dimension (e.g., a second cylindrical diameter) that corresponds to the first specific dimension and is larger than the first specific dimension. The size and positioning of the TMVs (312a, 312b) that are used for alignment marks (508a, 508b) may be different from other TMVs 312 that may provide an electrical circuit connectivity functionality. For example, as shown in FIG. 6B, in addition to the plurality of first TMVs 312a and the plurality of second TMVs 312b, which serve as alignment marks (508a, 508b), the intermediate structure 600 may further include a plurality of third TMVs 312c. As shown, each of the TMVs (312a, 312b, 312c) may have a symmetry-axis that may be parallel to a thickness direction (i.e., the z-axis).

The plurality of third TMVs 312c may be configured in a rectangular arrangement around a perimeter of a rectangular region (e.g., regions 506a to 506d in FIG. 5A) in which one or more semiconductor devices (e.g., semiconductor device 104d in FIG. 6B) may be placed. As shown in FIG. 6B, the third TMVs 312c may be arranged in a plurality of parallel rows of third TMVs 312c. In the example embodiment of FIG. 6B, there are four parallel rows of third TMVs 312c arranged along edges of the repeat unit 502. Alternatively, in other embodiments, the plurality of third TMVs 312c may be arranged in single rows as shown, for example, in FIGS. 5A to 5E, and for simplicity of illustration, in FIG. 6A. In still other embodiments, the plurality of third TMVs 312c may be arranged in two parallel rows, three parallel rows, five parallel rows, etc.

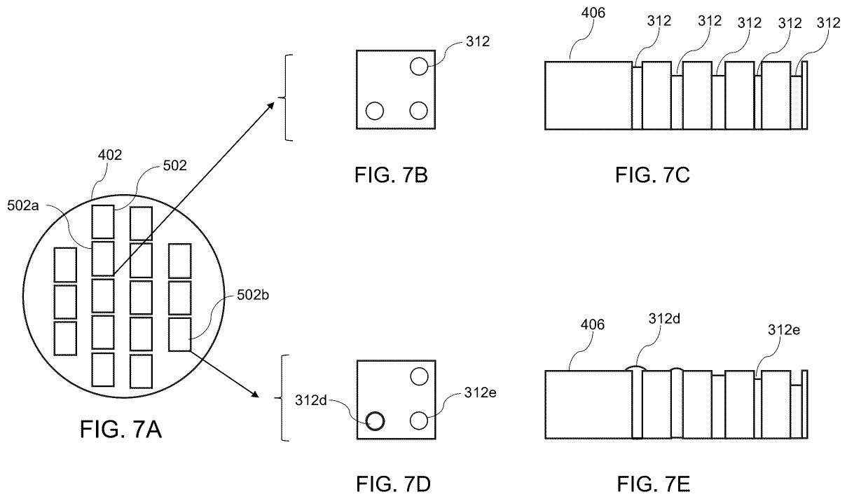

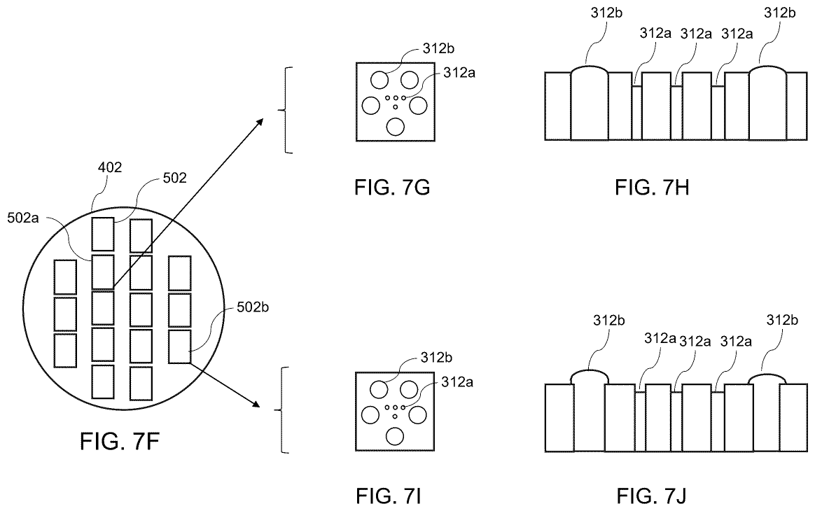

As shown in FIG. 6C, the plurality of first TMVs 312a of the first alignment marks 508a may have a small specific dimension and may be closely spaced. As such, they may provide highly accurate reference marks that may be used in a pick-and-place operation to accurately place the semiconductor devices (104a, 104b, 104c, 104d) within the intermediate structure 600. As described in greater detail with reference to FIGS. 7A to 7E, below, the plurality of second TMVs 312b may be “dummy” TMVs (DMY) that may serve the purpose of regulating a spatial distribution of electrical current density during the electroplating process to achieve improved specific diameter uniformity (SDU) and coplanarity of the TMVs (312a, 312b, 312c). As such, the plurality of second TMVs 312b may not be used, per se, as alignment marked when positioning the semiconductor devices (104a, 104b, 104c, 104d). The molding material 304 may have a slab geometry having a length direction (i.e., the x-direction), a width direction (i.e., y-direction), and a thickness direction (i.e., the z-direction). As mentioned above, each of the TMVs (312a, 312b, 312c) may have a symmetry-axis (i.e., a cylindrical symmetry-axis) that is parallel to the thickness direction (i.e., along the z-direction).

In the example embodiment of FIG. 6C, as shown, the distribution of TMVs (312a, 312b, 312c) includes the plurality of first TMVs 312a, the plurality of second TMVs 312b, and third TMVs 312c located in a central region of the repeat unit 502. The third TMVs 312c may serve an electrical circuit connectivity functionality, while in other embodiments, the TMVs located in a central region of the repeat unit 502 may be configured as second alignment marks 508b, as described above with reference to FIGS. 5B and 5C. In this regard, second alignment marks 508b (not shown in FIG. 6C) may be configured similarly to first alignment marks 508a and may include a plurality of first TMVs 312a and a plurality of second TMVs 312b. In other embodiments, the second alignment marks may include only third TMVs 312c, without the inclusion of first TMVs 312a and second TMVs 312b.

FIG. 7A is a top view of a wafer-level intermediate structure 700 that may be used in the formation of a related semiconductor package. FIG. 7B is a top view of a first portion of the intermediate structure of FIG. 7A showing through-molding-vias (TMVs) 312 that may be used as alignment marks and FIG. 7C is a vertical cross-sectional view of the first portion of the intermediate structure of FIG. 7A showing non-uniformities of TMVs 312. FIG. 7D is a top view of a second portion of the intermediate structure of FIG. 7A showing through-molding-vias (TMVs) that may be used as alignment marks and FIG. 7E is a vertical cross-sectional view of the second portion of the intermediate structure of FIG. 7A showing non-uniformities of TMVs.

The wafer-level intermediate structure 700 may include a plurality of repeat units 502. FIG. 7B illustrates a top view of a corner of a first repeat unit 502a and FIG. 7C illustrates a vertical cross-sectional view of a plurality of TMVs 312 formed in a patterned photoresist 406 near the corner of the first repeat unit 503a. Similarly, FIG. 7D illustrates a corner of a second repeat unit 502b and FIG. 7E illustrates a vertical cross-sectional view of a plurality of TMVs 312 formed in a patterned photoresist 406 near the corner of the second repeat unit 502b.

As shown in FIG. 7A, the corner of the first repeat unit 502a may located near a central region of the wafer-level intermediate structure 700, while the corner of the second repeat unit 502b may be located near an edge of the wafer-level intermediate structure 700. In this regard, the local environment experienced by the first repeat unit 502a and the second repeat unit 502b may be dissimilar. As such, during an electroplating process, a spatial distribution of electrical current density may vary as a function of position across the wafer-level intermediate structure 700 such that certain TMVs may be generated with a current density that is greater than that in regions in which other TMVs may be formed.

Since the electroplating deposition rate depends on the local current density, some TMVs may grow faster than others. As such, the resulting TMVs 312 may have a non-uniform distribution of heights, as shown in FIGS. 7C and 7E. In this regard, the TMVs 312 in the second repeat unit 502b may have larger heights near the edge of the second repeat unit 502b (e.g., near the left edge of FIG. 7E). Further, some TMVs 312d may grow to have a height that exceeds the height of the patterned photoresist. As such, some TMVs 312d may have a top portion that extends laterally beyond a diameter of the via holes. When imaged from above, such laterally extended TMVs 312d may appear to have a larger diameter than other TMVs 312e. Thus, such variation in the top-view diameters of the various TMVs (312d, 312e) may give rise to alignment inaccuracies when such TMVs (312d, 312e) are used as alignment marks.

FIG. 7F is a top view of a further wafer-level intermediate structure that may be used in the formation of a semiconductor package, according to various embodiments. FIG. 7G is a top view of a first portion of the intermediate structure of FIG. 7F showing details of a first alignment mark including a plurality of first TMVs and a plurality of second TMVs, and FIG. 7H is a vertical cross-sectional view of the first portion of the intermediate structure of FIG. 7F showing improved uniformity of the first TMVs, according to various embodiments. FIG. 7I is a top view of a second portion of the intermediate structure of FIG. 7F showing details of a second alignment mark including a plurality of first TMVs and a plurality of second TMVs, and FIG. 7J is a vertical cross-sectional view of the second portion of the intermediate structure of FIG. 7F showing improved uniformity of the first TMVs, according to various embodiments.

As shown in FIGS. 7H and 7J, the presence of the plurality of second TMVs 312b (i.e., “dummy” (DMY) TMVs having a larger specific dimension) may act to reduce non-uniformities in heights of the plurality of first TMVs 312a. In this regard, the second TMVs 312b may act to control an electrical current density to have a more uniform spatial distribution than that of the comparative embodiment of FIGS. 7B to 7E. Thus, although there may be variation in heights of the plurality of first TMVs 312a between those of the first repeat unit 502a (i.e., shown in FIG. 7H) relative to the heights of the plurality of first TMVs 312a of the second repeat unit 502b (i.e., shown in FIG. 7J), such heigh variations may not be apparent when the respective pluralities of first TMVs 312a are imaged from above. In this regard, as shown in FIGS. 7H and 7J, the heights of the TMVs 312a may be controlled so as to not exceed the thickness of the patterned photoresist 406. As such, the patterned photoresist 406 may constrain the plurality of first TMVs 312a to have a pre-determined diameter since the first TMVs 312a are constrained to not extend laterally above the surface of the patterned photoresist 406.

Thus, the first TMVs 312a of the first alignment marks 508a of FIGS. 7G and 7H and the first TMVs 312a of the second alignment marks 508b of FIGS. 7I and 7J may exhibit greater specific dimension (i.e., diameter) uniformity and a greater degree of coplanarity. As such, the first TMVs 312a of FIGS. 7F to 7J may provide alignment marks 508a that may allow increased alignment precision relative to existing alignment marks 312, such as those illustrated in the comparative embodiment of FIGS. 7A to 7E (i.e., TMVs 312 in FIGS. 7C and 7E). In contrast, any degree to which the plurality of second TMVs 312b may extend above the surface of the patterned photoresist 406 and may thus laterally extend beyond a diameter of a corresponding TMV via, as shown in FIGS. 7H and 7J, may not be consequential to alignment accuracy. This is because such second TMVs 312b are not used when aligning the semiconductor devices (104a, 104b, 104c, 104d) relative to the repeat units 502, but rather, are used as “dummy TMVs” due to the fact that their presence may be beneficial for controlling the electrical current distribution near the plurality of first TMVs 312a.

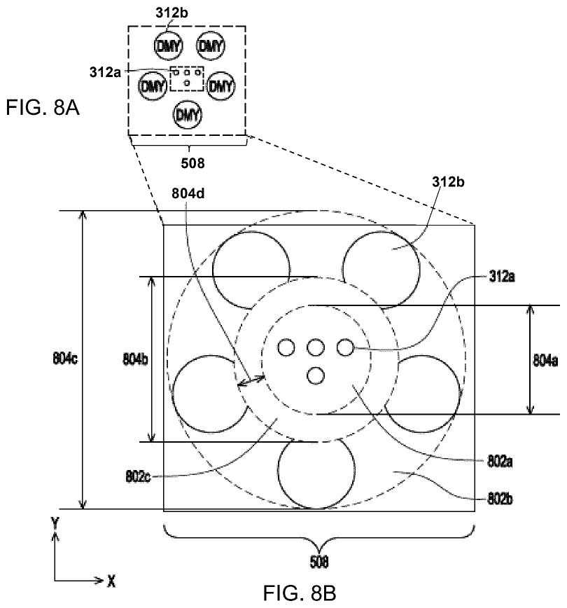

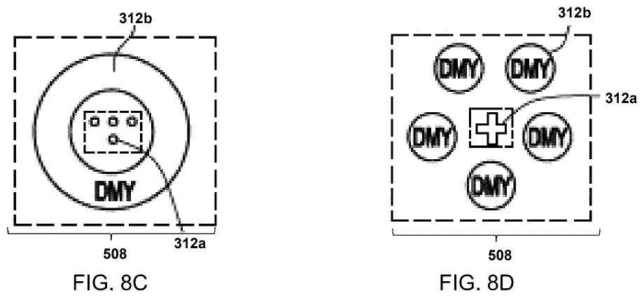

FIG. 8A is a top view of an alignment mark including first TMVs 312a and second TMVs 312b, and FIG. 8B is an enlarged top view of the alignment mark of FIG. 8A showing geometric details of the first TMVs 312a and second TMVs 312b, according to various embodiments. FIG. 8C is a top view of a further alignment mark including a plurality of first TMVs 312a and a single second TMV 312b, and FIG. 8D is a top view of a further alignment mark including a single first TMV 312a and a plurality of second TMVs 312b, according to various embodiments. As shown in FIG. 8A, an alignment mark 508 may include a plurality of first TMVs 312a surrounded by a plurality of second TMVs 312b. In other embodiments, as shown in FIG. 8C, the plurality of second TMVs 312b may be replaced by a single TMV 312b having an annular geometry. In a further embodiment, as shown in FIG. 8D, the plurality of first TMVs 312a may be replaced by a single first TMV 312a. As shown in FIG. 8D, the first TMV 312a may be a symmetrical shape (i.e., a cross) having rectangular elements. As such, the first TMV 312a may include at least one symmetry plane (i.e., along the x-axis or along the y-axis in this example embodiment).

As shown in FIG. 8B, the alignment mark 508 may include one or more first TMVs 312a located in a first region 802a and one or more second TMVs 312b located in a second region 802b that surrounds the first region. The first region may have a diameter 804a that is between 100 microns and 1000 microns, and the second region may have an annular geometry having an inner diameter 804b that is between 120 microns and 1600 microns and an outer diameter 804c that is between 270 microns and 2000 microns. As shown in FIG. 8B, the first region 802a and the second region 802b may be separated from one another by a third region 802c that also has an annular geometry having a width 804d is between 10 microns and 300 microns. According to various embodiments, each of the plurality of first TMVs 312a may have a first specific dimension (e.g., a first diameter) that is between 10 microns and 150 microns. Similarly, each of the plurality of second TMVs 312b may have a second specific dimension (e.g., a second diameter) that is between 100 microns and 500 microns.

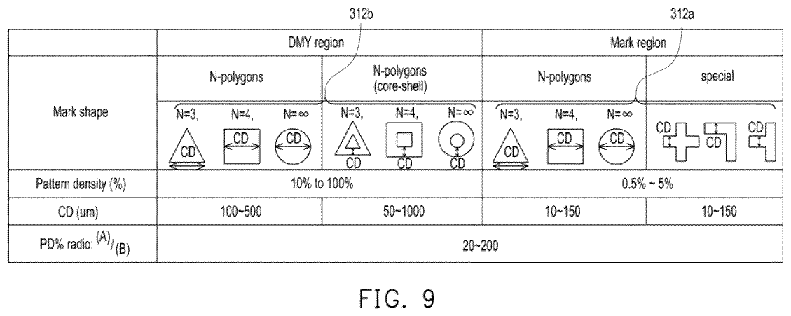

FIG. 9 illustrates top views of various types of TMVs (312a, 312b) that may be used to form an alignment mark 508, according to various embodiments. For example, one or more first TMVs 312a and the one or more second TMVs 312b may have a shape, within a plane perpendicular to a symmetry-axis (i.e., when viewed in a top view), that is circle, a triangle, a square, or an n-sided polygon. As shown, for such shapes, the first TMVs 312a may have a specific dimension (SD) (e.g., side, width, diameter, etc.) that is between 10 microns and 150 microns. Similarly the second TMVs 312b may have a SD (e.g., side, width, diameter, etc.) that corresponds to the first TMV 312a SD. The second TMV 312b SD may be between 100 microns and 500 microns. In further embodiments, the first TMVs 312a may be configured in various special shapes. For example, as shown in FIG. 9, each special shape may be configured to include two or more connected rectangular segments (e.g., a cross, an L-shape, a T-shape, etc.) having a specific dimension that is between 10 microns and 150 microns. In still-further embodiments, the second TMVs 312b may have a core-shell geometry with a SD that is between 50 microns and 1000 microns.

The spatial arrangement of the first TMVs 312a and the second TMVs 312b may correspond to a certain pattern density, defined as a percentage of a first area represented by the TMVs (312a, 312b) relative to a second area represented by surrounding molding material 304. In this regard, the one or more first TMVs 312a located in the first region 802a (e.g., see FIG. 8) may correspond to a first pattern density that is between 0.5% and 5%, and the one or more second TMVs 312b located in the second region 802b (e.g., see FIG. 8) may correspond to a second pattern density that is between 10% to 100%. Further, according to some embodiments, a ratio of the second pattern density to the first pattern density may be between 20 and 200.

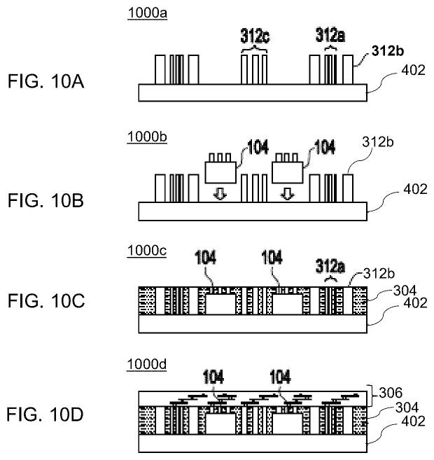

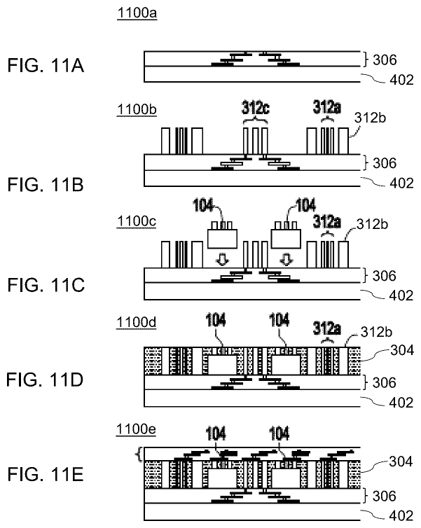

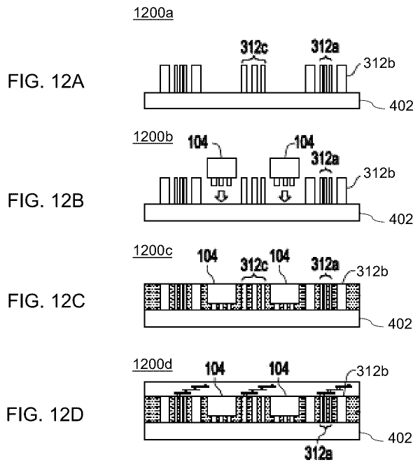

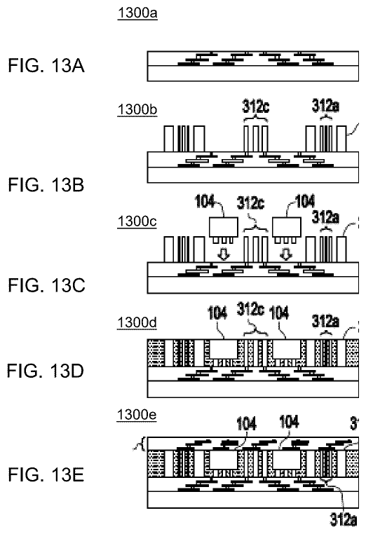

FIGS. 10A to 13E illustrate various alternative process flows including vertical cross-sectional views of intermediate structures (1000a to 1300e) that may be used in the formation of a semiconductor package 302, according to various embodiments. In this regard, the process flows of FIGS. 10A to 13E are similar to the process flow described with reference to FIGS. 4A to 4G, above, but provide various alternative configurations regarding the placement of one or more redistribution layers (306, 306a, 306b) and regarding the orientation of the semiconductor devices 104. For example, the in the process flows of FIGS. 10A to 10D and 11A to 11E, the semiconductor devices 104 may be oriented in a face-up configuration, while in the process flows of FIGS. 12A to 12D and 13A to 13E, the semiconductor devices 104 may be oriented in a face-down configuration. Further, according to various embodiments, the semiconductor package 302 may include a single redistribution layer 306 formed above the semiconductor devices 104 (e.g., see FIGS. 4G, FIG. 10A and FIG. 12D) or may include a first redistribution layer 306a and a second redistribution layer 306b respectively formed below and above the semiconductor devices 104 (e.g., see FIGS. 11E and 13E).

In the process flow of FIGS. 10A to 10D, TMVs (312a, 312b, 312c) may be first formed over a carrier substrate 402, as shown in FIG. 10A, and described in greater detail with reference to FIGS. 4A to 4D, above. Semiconductor devices 104 may then be attached to the carrier substrate 402 in a face-up configuration as shown in FIG. 10B and described in greater detail with reference to FIG. 4D, above. A molding material 304 may then be formed over the intermediate structure of FIG. 10B to form the intermediate structure of FIG. 10C, as described in greater detail with reference to FIG. 4E, above. A redistribution layer 306 may be formed over the intermediate structure of FIG. 10C to thereby form the intermediate structure of FIG. 10D, as described in greater detail with reference to FIGS. 4F and 4G above.

The process flow of FIGS. 11A to 11E may be similar to that of FIGS. 10A to 10D with the exception that, in a first process operation, a first redistribution layer 306a may be formed over the carrier substrate 402 as shown, for example, in FIG. 11A. The remaining process operations illustrated in FIGS. 11B to 11E may be similar to respective process operation illustrated in FIGS. 10A to 10D. The process operations illustrated in FIGS. 12A to 12D may be similar to those of FIGS. 10A to 10D with the exception that the semiconductor devices 104 may be attached to the carrier substrate 402 in a face-down configuration. Similarly, the process operations illustrated in FIGS. 13A to 13E may be similar to those of FIGS. 11A to 11D with the exception that the semiconductor devices 104 may be attached to the carrier substrate 402 in a face-down configuration.

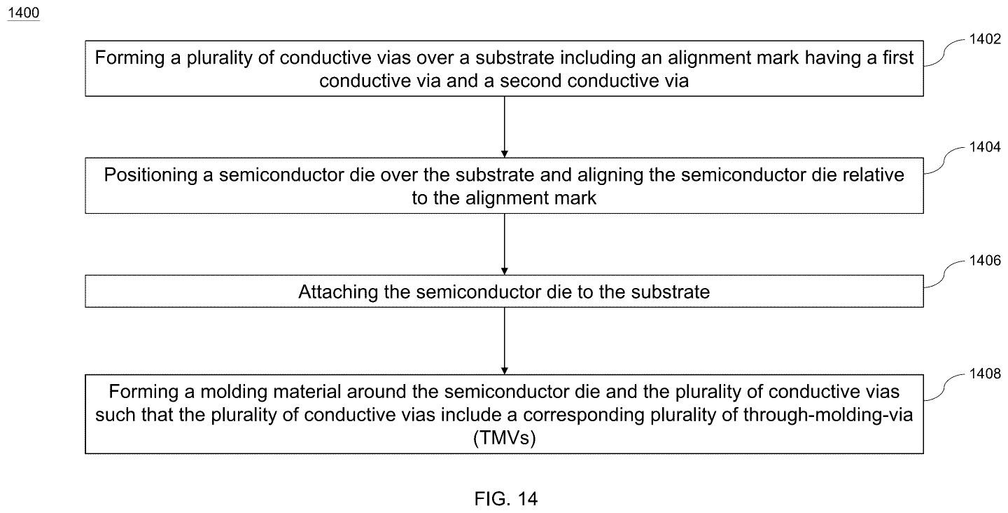

FIG. 14 is a flowchart illustrating process operations of a method 1400 of forming a semiconductor package 302, according to various embodiments. In operation 1402, the method 1400 may include forming a plurality of conductive vias (312, 312a, 312b) over a substrate 402 including an alignment mark (508a, 508b) having a first conductive via 312a and a second conductive via 312b. The first conductive via 312a may have a first specific dimension (e.g., cylindrical diameter) and the second conductive via 312b may include a second specific dimension (e.g., cylindrical diameter) that corresponds to the first specific dimension and is greater than the first specific dimension. In operation 1404, the method 1400 may include positioning a semiconductor device (104, 106) over the substrate 402 and aligning the semiconductor device (104, 106) relative to the alignment mark (508a, 508b). In operation 1406, the method 1400 may include attaching the semiconductor device (104, 106) to the substrate 402. In operation 1408, the method 1400 may include forming a molding material 304 around the semiconductor device (104, 106) and the plurality of conductive vias 312 such that the plurality of conductive vias 312 include a corresponding plurality of TMVs (312a, 312b).

In forming the plurality of conductive vias 312 according to operation 1402, the method 1400 may further include forming a patterned photoresist 406, having a plurality of via openings 408, over the substrate 402 and performing an electroplating process to deposit a conductive material in the via openings 408 to thereby form the plurality of conductive vias 312. In this regard, forming the patterned photoresist 406 further may include forming the via openings 408 such that the first specific dimension is between 100 microns and 500 microns and the second specific dimension is between 10 microns and 150 microns.

In forming the plurality of conductive vias (312, 312a, 312b) according to operation 1402, the method 1400 may further include forming the plurality of conductive vias 312 to be configured in a rectangular arrangement around a perimeter of a first rectangular region 506a. In attaching the semiconductor device (104, 106) to the substrate 402 according to operation 1406, the method 1400 may further include positioning, aligning, and attaching the semiconductor device (104, 106) to the substrate 402 within the first rectangular region 506a. In further embodiments, forming the plurality of conductive vias (312, 312a, 312b) according to operation 1402 of the method 1400 may further include forming the plurality of conductive vias (312, 312a, 312b) to be configured as a plurality of repeat units 502 separated by scribe lines 504, such each of the plurality of repeat units 502 may include one or more rectangular arrangements of conductive vias 312 that are each located around a perimeter of a respective rectangular area to thereby form a plurality of rectangular regions (506a, 506b, 506c, 506d). The method 1400 may further include forming one or more first alignment marks 508a to include the first conductive via 312a and the second conductive via 312b within each of the plurality of repeat units 502 and forming one or more second alignment mark 508s to include the first conductive via 312a and the second conductive via 312b within one or more scribe lines 504 between respective adjacent repeat units 502.

Referring to all drawings and according to various embodiments of the present disclosure, a semiconductor package 302 is provided. The semiconductor package 302 may include a semiconductor device (104, 106), a molding material 304 laterally surrounding the semiconductor device (104, 106), and an alignment mark (508a, 508b) including a TMV 312a and a second TMV 312b, each formed in the molding material 304. According to various embodiments, the first TMV 312a may include a first specific dimension and the second TMV 312b may include a second specific dimension that is larger than the first specific dimension. The semiconductor package 302 may further include a rectangular geometry and the alignment mark 508a may be located near a corner of the semiconductor package 302.

The alignment mark (508a, 508b) further may include one or more first TMVs 312a located in a first region 802a and one or more second TMVs 312b located in a second region 802b that surrounds the first region 802a. According to various embodiments, the first region 802a may include a diameter 804a that is between 100 microns and 1000 microns and the second region 802b may include an annular geometry having an inner diameter 804b that is between 120 microns and 1600 microns and an outer diameter 804c that is between 270 microns and 2000 microns. The first region 802a and the second region 802b may be separated from one another by a third region 802c that may include a further annular geometry having a width 804d is between 10 microns and 300 microns. According to various embodiments, the one or more first TMVs 312a located in the first region 802a may have a first pattern density that is between 0.5% and 5% and the one or more second TMVs 312b located in the second region 802b may have a second pattern density that is between 10% to 100%. In certain embodiments, a ratio of the second pattern density to the first pattern density may be between 20 and 200. In further embodiments, the one or more second TMVs 312b may include a single TMV 312b having an annular geometry.

According to further embodiments, the one or more first TMVs 312a and the one or more second TMVs 312b each have a shape, within a plane (i.e., the x-y plane) perpendicular to a symmetry axis (i.e., the z-axis), including a circle, a triangle, a square, or an n-sided polygon. Further, the first specific dimension may be between 10 microns and 150 microns and the second specific dimension may be between 100 microns and 500 microns. In certain embodiments, the one or more second TMVs 312b may have a core-shell geometry and the second specific dimension is between 50 microns and 1000 microns. Alternatively, the one or more first TMVs 312a may each have a shape, within a plane (i.e., the x-y plane) perpendicular to a symmetry axis (i.e., the z-axis), including two or more connected rectangular segments (e.g., see FIG. 9), and the second specific dimension may be between 10 microns and 150 microns. In certain embodiments, the one or more first TMVs 312a and the one or more second TMVs 312b each are arranged in a spatial configuration having at least one symmetry-plane (e.g., aligned with the y-axis in FIG. 8).

Referring to all drawings and according to various embodiments of the present disclosure, a further semiconductor package 302 is provided. The semiconductor package 302 may include a molding material 304 having a rectangular slab geometry including a length direction (i.e., the x-direction), a width direction (i.e., the y-direction), and a thickness direction (i.e., the z-direction), an alignment mark 508a including a first TMV 312a and a second TMV 312b each formed in the molding material 304 and having a respective symmetry axis (i.e., a cylindrical axis) parallel to the thickness direction (i.e., the z-direction). The first TMV 312a may have a first specific dimension and the second TMV 312b may have a second specific dimension that is larger than the first specific dimension. The semiconductor package 302 may further include a plurality of third TMVs 312c formed in the molding material 304, each including a further symmetry axis parallel to the thickness direction (i.e., the z-direction), such that the plurality of third TMVs is configured in a rectangular arrangement around a perimeter of a first rectangular region 506a in a plane spanned by the length direction and the width direction.

The semiconductor package 302 may further include a semiconductor device (104, 106) located within the first rectangular region 506a and laterally surrounded by the molding material 304, such that the first specific dimension is between 10 microns and 150 microns, and the second specific dimension is between 100 microns and 500 microns. According to various embodiments, the alignment mark 508 may further include one or more first TMVs 312a having a first pattern density that is between 0.5% and 5% and one or more second TMVs 312b having a second pattern density that is between 10% to 100%. The one or more first TMVs 312a and the one or more second TMVs 312b may each be arranged in a spatial configuration having at least one symmetry plane (e.g., aligned with the y-axis in FIG. 8).

Disclosed embodiments may provide advantages over existing semiconductor packages. In this regard, a semiconductor package 302 may include alignment marks (508a, 508b) having a first TMV 312a and a second TMV 312b. The second TMV 312b may have a specific dimension (e.g., side, width, diameter, etc.) that is larger than a specific dimension of a first TMV 312a. The first TMV 312a and the second TMV 312b may each be formed by an electroplating process, and the presence of the larger second TMV 312b may act to regulate an electroplating current density to have a more uniform spatial distribution than may otherwise occur if all of the TMVs (312, 312a, 312b) were the same size. In this regard, a resulting specific diameter uniformity and coplanarity of the resulting TMVs may be improved. As such, the smaller dimensions of the first TMVs 312a may allow for increased positioning accuracy when used as alignment markers in a pick-and-place process that may be used to position semiconductor devices (104, 106) within the semiconductor package 302.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a semiconductor device;
a molding material laterally surrounding the semiconductor device; and
an alignment mark comprising a first through-molding-via (TMV) and a second TMV, each formed in the molding material,
wherein the first TMV comprises a first specific dimension and the second TMV comprises a second specific dimension that is larger than the first specific dimension.

2. The semiconductor package of claim 1, wherein the semiconductor package comprises a rectangular geometry and the alignment mark is located near a corner of the semiconductor package.

3. The semiconductor package of claim 1, wherein the alignment mark further comprises:
one or more first TMVs located in a first region; and
one or more second TMVs located in a second region that surrounds the first region.

4. The semiconductor package of claim 3, wherein:
the first region comprises a diameter that is between 100 microns and 1000 microns; and
the second region comprises an annular geometry having an inner diameter that is between 120 microns and 1600 microns and an outer diameter that is between 270 microns and 2000 microns.

5. The semiconductor package of claim 4, wherein the first region and the second region are separated from one another by a third region that comprises a further annular geometry having a width is between 10 microns and 300 microns.

6. The semiconductor package of claim 4, wherein:
the one or more first TMVs located in the first region comprise a first pattern density that is between 0.5% and 5%; and
the one or more second TMVs located in the second region comprise a second pattern density that is between 10% to 100%.

7. The semiconductor package of claim 6, wherein a ratio of the second pattern density to the first pattern density is between 20 and 200.

8. The semiconductor package of claim 3, wherein the one or more second TMVs comprises a single TMV having an annular geometry.

9. The semiconductor package of claim 3, wherein the one or more first TMVs and the one or more second TMVs each comprise a shape, within a plane perpendicular to a symmetry-axis, comprising a circle, a triangle, a square, or an n-sided polygon.

10. The semiconductor package of claim 9, wherein:
the first specific dimension is between 10 microns and 150 microns; and
the second specific dimension is between 100 microns and 500 microns.

11. The semiconductor package of claim 9, wherein:
the one or more second TMVs comprises a core-shell geometry; and
the second specific dimension is between 50 microns and 1000 microns.

12. The semiconductor package of claim 3, wherein:
the one or more first TMVs each comprise a shape, within a plane perpendicular to a symmetry axis, comprising two or more connected rectangular segments; and
the second specific dimension is between 10 microns and 150 microns.

13. The semiconductor package of claim 3, wherein the one or more first TMVs and the one or more second TMVs each are arranged in a spatial configuration having at least one symmetry plane.

14. A semiconductor package, comprising:
a molding material comprising a rectangular slab geometry comprising a length direction, a width direction, and a thickness direction;
an alignment mark comprising a first TMV and a second TMV each formed in the molding material and having a respective symmetry axis parallel to the thickness direction, wherein the first TMV comprises a first specific dimension and the second TMV comprises a second specific dimension that is larger than the first specific dimension; and
a plurality of third TMVs formed in the molding material, each comprising a further symmetry axis parallel to the thickness direction, wherein the plurality of third TMVs is configured in a rectangular arrangement around a perimeter of a first rectangular region in a plane spanned by the length direction and the width direction.

15. The semiconductor package of claim 14, further comprising:
a semiconductor device located within the first rectangular region and laterally surrounded by the molding material, wherein:
the first specific dimension is between 10 microns and 150 microns; and
the second specific dimension is between 100 microns and 500 microns.

16. The semiconductor package of claim 14, wherein the alignment mark further comprises:
one or more first TMVs comprising a first pattern density that is between 0.5% and 5%; and
one or more second TMVs comprising a second pattern density that is between 10% to 100%,
wherein the one or more first TMVs and the one or more second TMVs each are arranged in a spatial configuration having at least one symmetry plane.

17. A method of forming a semiconductor package, comprising:
forming a plurality of conductive vias over a substrate including an alignment mark comprising a first conductive via and a second conductive via, wherein the first conductive via comprises a first specific dimension and the second conductive via comprises a second specific dimension that is greater than the first specific dimension;
positioning a semiconductor device over the substrate and aligning the semiconductor device relative to the alignment mark;
attaching the semiconductor device to the substrate; and
forming a molding material around the semiconductor device and the plurality of conductive vias such that the plurality of conductive vias comprise a corresponding plurality of through-molding-vias (TMVs).

18. The method of claim 17, wherein forming the plurality of conductive vias further comprises:
forming a patterned photoresist, comprising a plurality of via openings, over the substrate; and
performing an electroplating process to deposit a conductive material in the via openings to thereby form the plurality of conductive vias,
wherein forming the patterned photoresist further comprises forming the via openings such that the first specific dimension is between 100 microns and 500 microns and the second specific dimension is between 10 microns and 150 microns.

19. The method of claim 17, wherein forming the plurality of conductive vias further comprises:
forming the plurality of conductive vias to be configured in a rectangular arrangement around a perimeter of a first rectangular region, and
wherein attaching the semiconductor device to the substrate further comprises positioning, aligning, and attaching the semiconductor device to the substrate within the first rectangular region.

20. The method of claim 17, wherein forming the plurality of conductive vias further comprises:
forming the plurality of conductive vias to be configured as a plurality of repeat units separated by scribe lines, wherein each of the plurality of repeat units comprises one or more rectangular arrangements of conductive vias that are each located around a perimeter of a respective rectangular area to thereby form a plurality of rectangular areas;
forming one or more first alignment marks comprising the first conductive via and the second conductive via within each of the plurality of repeat units; and
forming one or more second alignment marks comprising the first conductive via and the second conductive via within one or more scribe lines between respective adjacent repeat units.
